(19) United States
(12) Patent Application Publication
(10) Pub. No.: US 2024/0266490 A1
(43) Pub. Date: Aug. 8, 2024

(54) DISPLAY DEVICE

(71) Applicant: Japan Display Inc., Tokyo (JP)

(72) Inventors: Keisuke ASADA, Minato-ku (JP); Kazuyuki YAMADA, Minato-ku (JP); Kenichi TAKEMASA, Minato-ku (JP); Daiki ISONO, Minato-ku (JP)

(73) Assignee: Japan Display Inc., Tokyo (JP)

(21) Appl. No.: 18/625,751

(22) Filed: Apr. 3, 2024

Related U.S. Application Data
(63) Continuation of application No. PCT/JP2022/036267, filed on Sep. 28, 2022.

(30) Foreign Application Priority Data
Oct. 14, 2021 (JP) 2021-168732

(51) Int. Cl. H01L 33/62; H01L 25/16; H01L 33/58

(52) U.S. Cl. CPC H01L 33/62; H01L 25/167; H01L 33/58

(57) ABSTRACT

A display device capable of providing a high production efficiency LED display including: a wiring electrically connected to a transistor of a pixel circuit, a layer including a top surface of the wiring being formed of a first material; a connecting electrode electrically connected to the wiring, a layer including a top surface of the connecting electrode being formed of a second material; and an LED element mounted on the connecting electrode, wherein an absorption rate of the first material with respect to infrared radiation is smaller than an absorption rate of the second material with respect to infrared radiation.

### CROSS REFERENCE TO RELATED APPLICATIONS

This application is a Continuation of International Patent Application No. PCT/JP2022/036267, filed on Sep. 28, 2022, which claims the benefit of priority to Japanese Patent Application No. 2021-168732 filed on Oct. 14, 2021, the entire contents of which are incorporated herein by reference.

### FIELD

An embodiment of the present invention relates to a display device. In particular, an embodiment of the present invention relates to a display device on which an LED (Light Emitting Diode) element is mounted.

### BACKGROUND

An LED display in which minute LED elements are mounted on each pixel has been developed as a next-generation display device in recent years. An LED display generally has a structure in which a plurality of LED elements is mounted on a circuit substrate constituting a pixel array. The circuit substrate includes a drive circuit for causing LED to emit light at a position corresponding to each pixel. These drive circuits are electrically connected to each LED element, respectively.

The drive circuit and the LED element described above are electrically connected via a connecting electrode. Specifically, a connecting electrode arranged on the drive circuit side and a terminal electrode arranged on the LED element side are electrically connected. For example, Japanese laid-open patent publication No. 2020-67626 describes a technique of bonding the LED element and the circuit substrate using a conductive material.

### SUMMARY

A display device according to an embodiment of the present invention includes: a wiring electrically connected to a transistor of a pixel circuit, a layer including a top surface of the wiring being formed of a first material; a connecting electrode electrically connected to the wiring, a layer including a top surface of the connecting electrode being formed of a second material; and an LED element mounted on the connecting electrode, wherein an absorption rate of the first material with respect to infrared radiation is smaller than an absorption rate of the second material with respect to infrared radiation.

A display device according to an embodiment of the present invention includes: a wiring electrically connected to a transistor of a pixel circuit, a layer including a top surface of the wiring being formed of an aluminum layer; an insulating layer having an opening and covering a top surface of the aluminum layer in a region other than a region arranged with the opening; a connecting electrode arranged above the insulating layer, including a first conductive layer, a second conductive layer and a third conductive layer, and electrically connected to the wiring via the opening; and an LED element mounted on the connecting electrode, wherein the second conductive layer has a barrier property preventing diffusion of a material included in the first conductive layer and a material included in the third conductive layer.

### BRIEF DESCRIPTION OF DRAWINGS

FIG. 1 is a plan view showing a schematic configuration of a display device according to an embodiment of the present invention.

FIG. 2 is a diagram showing a circuit configuration of a display device according to an embodiment of the present invention.

FIG. 3 is a circuit diagram showing a configuration of a pixel circuit of a display device according to an embodiment of the present invention.

FIG. 4 is a cross-sectional view showing a configuration of a pixel of a display device according to an embodiment of the present invention.

FIG. 5 is a partially enlarged view of FIG. 4.

FIG. 6 is a planar layout diagram showing a configuration of a pixel of a display device according to an embodiment of the present invention.

FIG. 7 is a planar layout diagram showing a configuration of a pixel of a display device according to an embodiment of the present invention.

FIG. 8 is a cross-sectional view showing a configuration of a pixel of a display device according to an embodiment of the present invention.

FIG. 9 is a partially enlarged view of FIG. 8.

### DESCRIPTION OF EMBODIMENTS

Hereinafter, embodiments of the present invention will be described with reference to the drawings and the like. However, the present invention can be implemented in various forms without departing from the gist thereof. The present invention is not to be construed as being limited to the description of the embodiments exemplified below. In the drawings, the widths, thicknesses, shapes, and the like of the respective portions may be schematically represented in comparison with actual embodiments for clarity of explanation. However, the drawings are merely examples, and do not limit the interpretation of the present invention.

In describing embodiments of the present invention, a direction from a substrate toward an LED element is referred to as “on or above”, and the opposite direction is referred to as “under or below”. However, the expression “on or above” or “under or below” merely describes the vertical relationship of each element. For example, the expression that an LED element is arranged above a substrate includes the case where another member is interposed between the substrate and the LED element. Furthermore, the expression “above” or “below” include not only the case where each element overlap in a plan view, but also the case where they do not overlap. The expression “directly above” or “directly below” refers to the case where each element overlap in a plan view.

In the present specification and claims, a plurality of configurations formed by subjecting a certain film to a processing such as etching may be described as a configuration having different functions or roles. The plurality of configurations is described as being composed of the same layer structure and the same material and being in the same layer. The plurality of configurations formed by different processes is arranged above the same other configuration and in contact with the other configuration.

The expressions “a includes A, B, or C,” “a includes any of A, B, and C,” and “a includes one selected from a group consisting of A, B, and C,” do not exclude the case where a includes a plurality of combinations of A to C unless otherwise specified. Furthermore, these expressions do not exclude the case where a includes other elements.

In describing the embodiments of the present invention, elements having the same functions as those described above are denoted by the same reference signs or the same reference signs with symbols such as alphabets, and description thereof may be omitted. For example, when there is a plurality of elements to which a certain reference sign is attached in the drawings, “a”, “b”, and the like may be attached to reference signs to distinguish them. On the other hand, when it is not necessary to distinguish each element, the description will be made using only the reference signs indicating the elements. Similarly, when an element needs to be described separately in the respective colors of RGB, a symbol R, G, or B may be attached to a sign indicating the element to distinguish the element. On the other hand, when the elements do not need to be described separately for the respective colors of RGB, the elements will be described using only the reference signs indicating the elements.

In the case where an LED element is mounted on a substrate in which a drive circuit is arranged as described above, a connecting electrode and a terminal electrode are bonded by irradiating laser light from the LED element side in a state where the connecting electrode and the terminal electrode are in contact with each other. For example, infrared rays are used as the laser light because the laser light is transmitted through a semiconductor substrate in which the LED element is arranged and irradiated onto the connecting electrode and the terminal electrode. Infrared laser light is absorbed by a metal used as a wiring included in the drive circuit. Therefore, heat is generated in the wiring irradiated with laser light, and the drive circuit may be destroyed by the heat.

In order to solve the above-described problems, conventionally, when laser irradiation is performed, for example, it is required to cover the wiring or the like with a mask or the like so that the laser light is not irradiated onto the wiring or the like of the drive circuit. However, when the laser irradiation is performed using a mask, a step of aligning the mask with respect to the drive circuit is required. As a result, there is a problem that the production efficiency decreases.

An object of the present invention is to provide a highly productive LED display.

### First Embodiment

### [Configuration of Display Device]

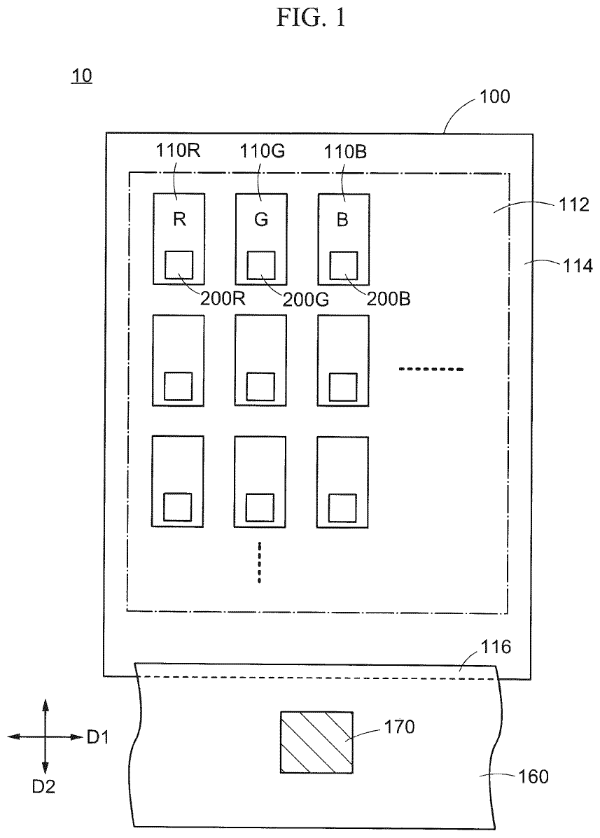

A configuration of a display device 10 according to an embodiment of the present invention will be described with reference to FIG. 1 to FIG. 7.

FIG. 1 is a plan view showing a schematic configuration of the display device 10 according to a first embodiment of the present invention. The display device 10 includes a circuit substrate 100, a flexible printed circuit substrate 160 (FPC 160) and an IC element 170, as shown in FIG. 1. The display device 10 is divided into a display region 112, a peripheral region 114, and a terminal region 116.

The display region 112 is a region where a plurality of pixels 110 including an LED element 200 is arranged in a row direction (direction D1) and a column direction (direction D2). Specifically, a red pixel 110R including a red LED element 200R, a green pixel 110G including a green LED element 200G, and a blue pixel 110B including a blue LED element 200B are arranged in the display region 112 in the present embodiment. The display region 112 functions as a region that displays an image corresponding to a video signal (data signal).

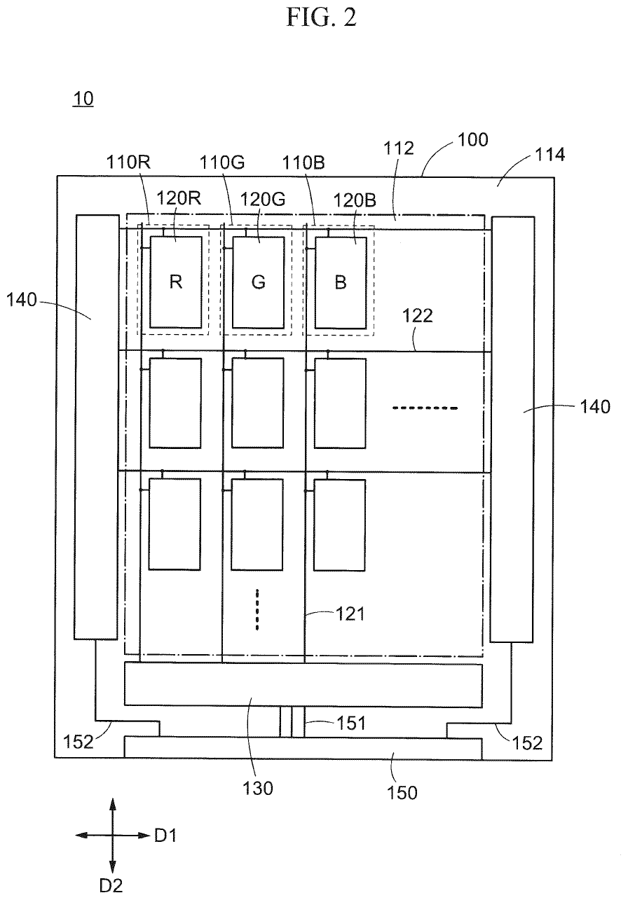

The peripheral region 114 is a region around the display region 112. The peripheral region 114 is a region where driver circuits (a data driver circuit 130 and a gate driver circuit 140 shown in FIG. 2) for controlling pixel circuits (pixel circuits 120R, 120G and 120B shown in FIG. 2) arranged in each pixel 110 is arranged.

The terminal region 116 is a region where a plurality of wirings connected to the above-described driver circuit is aggregated. The flexible printed circuit substrate 160 is electrically connected to the plurality of wirings in the terminal region 116. A video signal or a control signal output from an external device (not shown) is input to the IC element 170 via a wiring (not shown) arranged in the flexible printed circuit substrate 160. The IC element 170 generates control signals required for various signal processes and display control with respect to the video signal. The video signal and the control signal output from the IC element 170 are input to the display device 10 via the flexible printed circuit substrate 160.

### [Circuit Configuration of Display Device]

FIG. 2 is a diagram showing a configuration of the display device according to the first embodiment of the present invention. The pixel circuit 120 corresponding to each pixel 110 is arranged in the display region 112, as shown in FIG. 2. The pixel circuit 120R, the pixel circuit 120G, and the pixel circuit 120B are respectively arranged corresponding to the pixel 110R, the pixel 110G, and the pixel 110B, in the present embodiment. That is, the plurality of pixel circuits 120 is arranged in the display region 112 in the row direction (direction D1) and the column direction (direction D2).

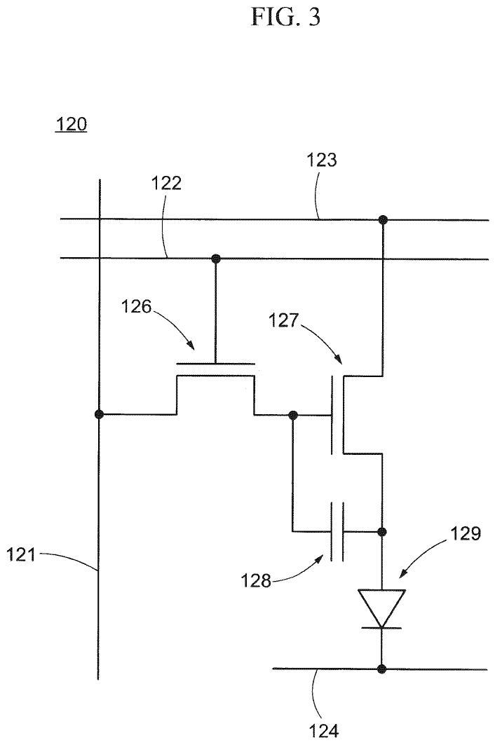

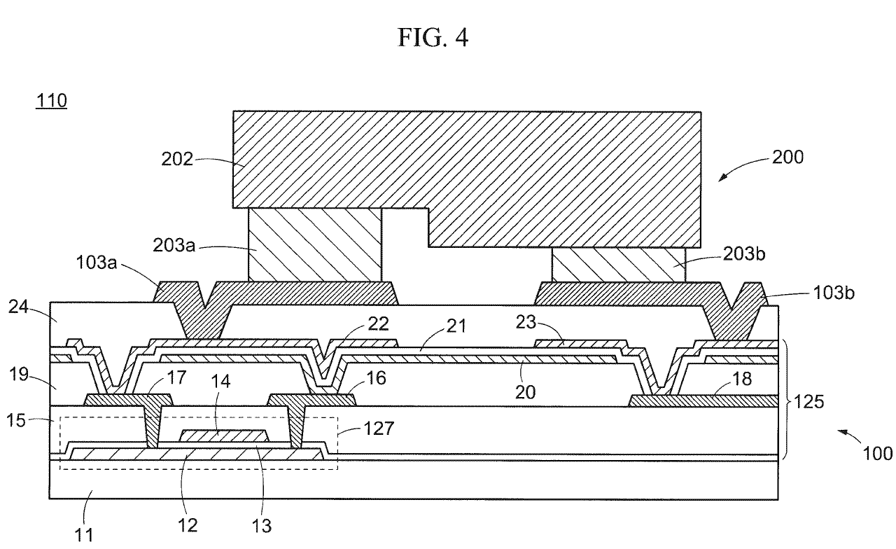

FIG. 3 is a circuit diagram showing a configuration of the pixel circuit 120 in the display device 10 according to the first embodiment. The pixel circuit 120 is arranged in a region surrounded by a data line 121, a gate line 122, an anode power line 123, and a cathode power line 124. The pixel circuit 120 of the present embodiment includes a select transistor 126, a drive transistor 127, a storage capacitor 128, and an LED 129. The LED 129 corresponds to the LED element 200 shown in FIG. 1. Among the pixel circuit 120, circuit elements other than the LED 129 correspond to a drive circuit 125 (see FIG. 4) arranged in the circuit substrate 100. That is, the pixel circuit 120 is completed by mounting the LED element 200 on the drive circuit 125.

A source electrode, a gate electrode, and a drain electrode of the select transistor 126 are respectively connected to the data line 121, the gate line 122, and a gate electrode of the drive transistor 127, as shown in FIG. 3. The source electrode, the gate electrode, and the drain electrode of the drive transistor 127 are respectively connected to the anode power line 123 and the drain electrode and the LED 129 of the select transistor 126. The storage capacitor 128 is connected between the gate electrode and the drain electrode of the drive transistor 127. That is, the storage capacitor 128 is connected to the drain electrode of the select transistor 126. An anode and a cathode of the LED 129 are respectively connected to the drain electrode of the drive transistor 127 and the cathode power line 124.

A gradation signal for determining an emission intensity of the LED 129 is supplied to the data line 121. A gate signal for selecting the select transistor 126 to which the gradation signal is written is supplied to the gate line 122. The gradation signal is accumulated in the storage capacitor 128 when the select transistor 126 is turned ON. After that, a drive current corresponding to the gradation signal flows through the drive transistor 127 when the drive transistor 127 is turned ON. The drive current output from the drive transistor 127 is input to the LED 129, and then the LED 129 emits light with a light emission intensity corresponding to the gradation signal.

The data driver circuit 130 is arranged at a position adjacent to the display region 112 in the column direction (direction D2) with reference to FIG. 2. The gate driver circuit 140 is arranged at a position adjacent to the display region 112 in the row direction (direction D1). Although a configuration in which two gate driver circuits 140 are arranged on both sides of the display region 112 is exemplified in the present embodiment, it may be a configuration in which only one of the gate driver circuits 140 is arranged.

Both the data driver circuit 130 and the gate driver circuit 140 are arranged in the peripheral region 114. However, the region where the data driver circuit 130 is arranged is not limited to the peripheral region 114. For example, the data driver circuit 130 may be arranged in the flexible printed circuit substrate 160.

The data line 121 shown in FIG. 3 extends in the column direction from the data driver circuit 130 and is connected to the source electrode of the select transistor 126 in each pixel circuit 120. The gate line 122 extends in the row direction from the gate driver circuit 140 and is connected to the gate electrode of the select transistor 126 in each pixel circuit 120.

A terminal portion 150 is arranged in the terminal region 116. The terminal portion 150 is connected to the data driver circuit 130 via a connection wiring 151. Similarly, the terminal portion 150 is connected to the gate driver circuit 140 via a connection wiring 152. Further, the terminal portion 150 is connected to the flexible printed circuit substrate 160.

### [Cross Sectional Structure of Pixel]

FIG. 4 is a cross-sectional view showing a configuration of the pixel 110 in the display device 10 according to the first embodiment of the present invention. The pixel 110 includes the drive transistor 127 arranged above the insulating substrate 11. A glass substrate, a plastic substrate, a ceramic substrate, or a substrate in which an insulating layer is arranged above a metal substrate is used as the insulating substrate 11. In the case where the plastic substrate is used as the insulating substrate 11, flexibility can be applied to the display device 10.

The drive transistor 127 includes a semiconductor layer 12, a gate insulating layer 13, and a gate electrode 14. A source electrode 16 and a drain electrode 17 are connected to the semiconductor layer 12 via an insulating layer 15. Although not shown, the gate electrode 14 is connected to the drain electrode of the select transistor 126 shown in FIG. 3. The source electrode 16 is electrically connected to the anode power line 123 by a connection wiring 20 arranged above a planarization layer 19. The planarization layer 19 is a transparent resin layer using a resin material such as polyimide or acryl.

The source electrode 16, the drain electrode 17, and the connection wiring 20 are composed of a metal material including tantalum (Ta), tungsten (W), molybdenum (Mo), titanium (Ti), or aluminum (Al). For example, a wiring, which is a stacked structure (hereinafter referred to as “Ti/Al/Ti”) in which an aluminum layer is sandwiched between titanium layers, is used as the source electrode 16 and the drain electrode 17. A wiring which is a stacked structure (hereinafter referred to as “Al/Ti”) of titanium (lower layer) and aluminum (upper layer) is used as the connection wiring 20. However, the structures of the source electrode 16, the drain electrode 17, and the connection wiring 20 are not limited to the above examples. These structures may not be a stacked structure, and materials other than those described above may be used. For example, a transparent conductive layer using a metal oxide material such as an ITO may be used as the connection wiring 20.

An insulating layer 21 composed of silicon oxide, silicon nitride, or the like is arranged above the connection wiring 20. An anode wiring 22 and a cathode wiring 23 are arranged above the insulating layer 21. These wirings are composed of metal materials. The anode wiring 22 is connected to the drain electrode 17 via an opening arranged in the planarization layer 19 and the insulating layer 21. The cathode wiring 23 is connected to a wiring 18 via the opening arranged in the planarization layer 19 and the insulating layer 21. That is, the anode wiring 22 is electrically connected to the drive transistor 127.

The anode wiring 22 and the cathode wiring 23 are composed of a metal material including tantalum, tungsten, molybdenum, titanium, or aluminum, as described above. For example, the “Al/Ti” stacked structure is used as the anode wiring 22 and the cathode wiring 23. The materials and physical properties required for the anode wiring 22 and the cathode wiring 23 will be described later.

The drive circuit 125 is completed by forming the anode wiring 22 and the cathode wiring 23, as described above. Although not shown in FIG. 4, elements such as the select transistor 126 and the storage capacitor 128 are formed in addition to the drive transistor 127.

An insulating layer 24 is arranged above the anode wiring 22 and the cathode wiring 23. The insulating layer 24 is in contact with the aluminum layer, which is the uppermost layer of each of the anode wiring 22 and the cathode wiring 23. An opening is arranged in the insulating layer 24. An inorganic insulating material such as silicon oxide, silicon nitride, aluminum oxide, or aluminum nitride is used as the insulating layer 24. Alternatively, a transparent resin layer using resin material such as polyimide, acryl or the like may be used as the insulating layer 24. These materials may be used as the insulating layer 24 in a single layer or in a stacked layer. Although details will be described later, the insulating layer 24 covers top surfaces of the anode wiring 22 and the cathode wiring 23 and suppresses the surfaces of these wirings from being oxidized.

Connecting electrodes 103a and 103b are arranged above the insulating layer 24 and in the opening arranged in the insulating layer 24. Each of the connecting electrodes 103a and 103b is connected to the anode wiring 22 and the cathode wiring 23 via the opening arranged in the insulating layer 24. The connecting electrode 103a functions as an intermediate layer electrically connecting the drive transistor 127 and the LED element 200. The connecting electrode 103b functions as an intermediate layer electrically connecting the LED element 200 and the cathode wiring 23. The connecting electrodes 103a and 103b are composed of a metal material including gold (Au), silver (Ag), copper (Cu), tin (Sn), titanium (Ti), or nickel (Ni). Although details will be described later, a stacked structure of “Sn/Cu/Ti” is used as the connecting electrodes 103a and 103b. The materials and the physical properties required for the connecting electrode 103 and the connecting electrode 103b will be detailed later.

The LED element 200 is mounted on the connecting electrodes 103a and 103b. The LED element 200 includes a semiconductor layer 202 and terminal electrodes 203a and 203b. The semiconductor layer 202 functions as a photoelectric conversion layer including an n-type semiconductor layer and a p-type semiconductor layer. Although the semiconductor layer 202 is composed of a material containing gallium nitride in the present embodiment, the present invention is not limited to this example.

The anode of the LED 129 is connected to the drive transistor 127 as shown in FIG. 3 in the present embodiment. The terminal electrode 203a of the LED element 200 in FIG. 4 is connected to the anode wiring 22 connected to the drain electrode 17 of the drive transistor 127. The terminal electrode 203b of the LED element 200 is connected to the cathode wiring 23. The cathode wiring 23 is electrically connected to the cathode power line 124 shown in FIG. 3. Therefore, the terminal electrode 203a is connected to the p-type semiconductor layer of the semiconductor layer 202 and is connected to the connecting electrode 103a. On the other hand, the terminal electrode 203b is connected to the n-type semiconductor layer of the semiconductor layer 202 and is connected to the connecting electrode 103b.

Gold (Au) is used as the terminal electrode 203 in the present embodiment. Although details will be described later, the connecting electrode 103 and the terminal electrode 203 are bonded to each other by irradiating laser light. Therefore, an alloy layer (a eutectic alloy containing tin and gold) (not shown) is present between the connecting electrode 103 and the terminal electrode 203.

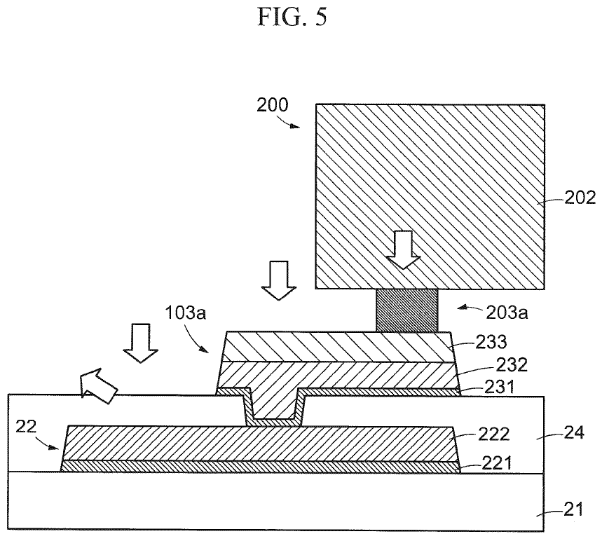

FIG. 5 is a partially enlarged view of FIG. 4. FIG. 5 is an enlarged view of the structure of the anode wiring 22, the connecting electrode 103a, and the terminal electrode 203a of FIG. 4. The anode wiring 22 includes a first conductive layer 221 and a second conductive layer 222, as shown in FIG. 5. The connecting electrode 103a includes a first conductive layer 231, a second conductive layer 232, and a third conductive layer 233.

The second conductive layer 222 is a layer including the top surface of the anode wiring 22. The second conductive layer 222 is formed of a first material. The third conductive layer 233 is a layer including a top surface of the connecting electrode 103a. The third conductive layer 233 is formed of a second material. The absorption rate of the first material with respect to infrared radiation is smaller than the infrared absorption rate of the second material. In other words, when comparing the absorption rate for light with a wavelength of 1 μm, the absorption rate of the first material is smaller than the absorption rate of the second material. A thickness of the second conductive layer 222 may be 1 μm or more.

A material having higher heat resistance than the second conductive layer 222, higher adhesion to the lower layer (the insulating layer 21), lower contact resistance with the conductive layer arranged below the insulating layer 21, and lower contact resistance with the second conductive layer 222 is used as the first conductive layer 221. For example, tantalum, tungsten, molybdenum, or titanium may be used as the first conductive layer 221.

A material in which a eutectic alloy is formed by heat generated by infrared laser light irradiation can be used as the material of each of the third conductive layer 233 and the terminal electrode 203. Although the configuration in which tin (Sn) is used as the third conductive layer 233, and gold (Au) is used as the terminal electrode 203 is exemplified in the present embodiment as described above, it is not limited to the above-described materials if both form a eutectic alloy. A tin alloy containing tin, silver, or copper may be used as the third conductive layer 233. Tin or a tin alloy may be used as the terminal electrode 203 in addition to gold.

The second conductive layer 232 suppresses the first conductive layer 231 and the third conductive layer 233 from diffusing to each other due to the heat generated by infrared laser light irradiation. For example, nickel is used as the second conductive layer 232. The second conductive layer 232 may be referred to as a barrier layer.

The first conductive layer 231 is a layer for securing contact with the second conductive layer 222 of the connecting electrode 103a, and is a layer functioning as a base of the second conductive layer 232. For example, in the case where copper is formed as the second conductive layer 232 by an electric field plating method, the first conductive layer 231 functions as a seed layer of the second conductive layer 232, which is a plating layer. Titanium, nickel, copper, and a stacked structure of copper and titanium are used as the first conductive layer 231.

Titanium is used as the first conductive layer 221 and aluminum is used as the second conductive layer 222, in the present embodiment. Titanium is used as the first conductive layer 231, copper is used as the second conductive layer 232, and tin is used as the third conductive layer. That is, the “first material” corresponds to aluminum, and the “second material” corresponds to tin. The absorption rate of aluminum with respect to infrared radiation as the first material is smaller than the absorption rate of tin with respect to infrared radiation as the second material. The absorption rate of aluminum with respect to infrared radiation is about 13%, and the absorption rate of tin with respect to infrared radiation is about 40%.

In the case where the LED element 200 is mounted on the circuit substrate 100, as shown in FIG. 4, the terminal electrode 203 and the connecting electrode 103 are irradiated with infrared laser light from above the LED element 200 with the terminal electrode 203 arranged above the connecting electrode 103 (see arrows in FIG. 5). The infrared laser light is transmitted through the semiconductor layer 202 of the LED element 200 and absorbed by the gold arranged as the terminal electrode 203 and the tin arranged as the third conductive layer 233 of connecting electrode 103. When the laser light is absorbed by the terminal electrode 203 and the third conductive layer 233, the terminal electrode 203 and the third conductive layer 233 are heated, and a eutectic alloy of gold and tin is formed. The terminal electrode 203 and the third conductive layer 233 are bonded to each other by the laser irradiation as described above.

In the case where the laser light is irradiated to a metal other than the terminal electrode 203 and the connecting electrode 103 at the time of bonding by the laser irradiation, heat is generated at the irradiated portion, which may adversely affect the transistor elements and capacity elements constituting the display device. Therefore, it is desired to suppress the heat generation due to the laser irradiation as much as possible at portions other than the above-described bonding portion. The second conductive layer 222 has a lower absorption rate with respect to infrared radiation than the third conductive layer 233 in the present embodiment. In other words, the second conductive layer 222 has a higher reflectance for infrared than the third conductive layer 233. Therefore, even when the laser irradiation is performed without using a mask, heat generation due to the second conductive layer 222 (the anode wiring 22) can be suppressed, so it is possible to suppress the adverse effects on the transistor device and capacity element. Since the thickness of the second conductive layer 222 is 1 μm or more, even if heat is generated in the second conductive layer 222 due to the laser irradiation, it is possible to suppress the heat from being transmitted to the transistor element or the like arranged below the anode wiring 22 and the cathode wiring 23.

Since a semiconductive material containing gallium nitride that transmits near-infrared light is used as the semiconductor layer 202 in the present embodiment, a YAG laser or a light (wavelength: about 1064 nm) emitted from a YVO₄ laser is used as the laser light used for the laser irradiation.

The insulating layer 24 covers the top surface of the second conductive layer 222, so that the progress of the oxidization of the top surface of the second conductive layer 222 is suppressed. Although a natural oxide film may be formed on the top surface of the second conductive layer 222 until the insulating layer 24 is formed, the oxide film is not formed after the insulating layer 24 is formed. Although the absorption rate of aluminum with respect to infrared radiation is about 13% as described above, the absorption rate of aluminum oxide formed on the surface of aluminum with respect to infrared radiation is about 40%. That is, when the second conductive layer 222 is oxidized, the absorption rate with respect to infrared radiation suddenly increases. Therefore, in the case where aluminum is used as the second conductive layer 222, the second conductive layer 222 (the anode wiring 22) generates heat as the aluminum oxide absorbs infrared when the oxidation on the surface progresses. In order to suppress such heat generation, the insulating layer 24 is formed above the second conductive layer 222. The absorption rate of the insulating layer 24 with respect to infrared radiation is sufficiently smaller than the absorption rate of aluminum with respect to infrared radiation.

Since the opening is arranged in the insulating layer 24 and the first conductive layer 231 is arranged in the opening in the present embodiment, the second conductive layer 222 and the first conductive layer 231 are electrically connected. In order to ensure good conduction between the second conductive layer 222 and the first conductive layer 231, the opening is formed, and then reverse sputtering is performed immediately before the deposition of the first conductive layer 231. A natural oxide film or the like formed on the surface of the second conductive layer 222 exposed by the opening is removed by the reverse sputtering, and good conduction between the second conductive layer 222 and the first conductive layer 231 can be obtained.

### [Planar Layout of Pixel]

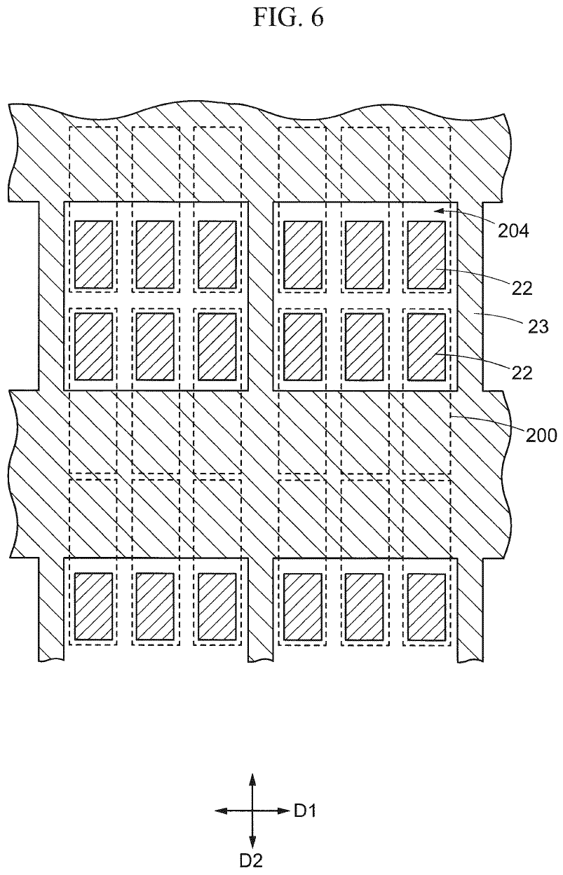

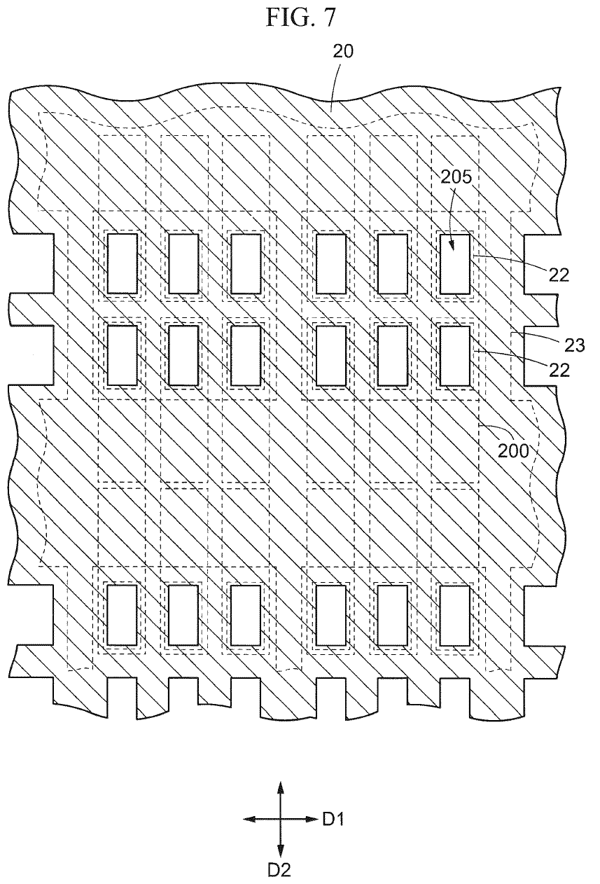

FIG. 6 and FIG. 7 are planar layout diagram showing a configuration of pixels of a display device according to an embodiment of the present invention. FIG. 6 is a diagram showing a positional relationship between the anode wiring 22 and the cathode wiring 23 of the LED element 200 and the LED element 200, respectively. FIG. 7 is a diagram showing a positional relationship between the members shown in FIG. 6 and the connection wiring 20.

The cathode wiring 23 has a grid-like configuration extending in the direction D1 and the direction D2, as shown in FIG. 6. An opening 204 is arranged in the grid-shaped cathode wiring 23. The anode wiring 22 is arranged in the opening 204. A plurality of anode wirings 22 is arranged in one opening 204. The LED element 200 is arranged so as to span the cathode wiring 23 and the anode wiring 22. The connecting electrode 103a and the terminal electrode 203a shown in FIG. 4 are arranged in a region overlapping both the anode wiring 22 and the LED element 200, in the layout of FIG. 6. The connecting electrode 103b and the terminal electrode 203b shown in FIG. 4 are arranged in the region overlapping both the cathode wiring 23 and the LED element 200.

The anode wiring 22 is arranged separately for each LED element 200. On the other hand, the cathode wiring 23 is arranged in common to the plurality of LED elements 200. With this configuration, the emission intensity of the LED element 200 is determined depending on the drive current output from the drive transistor 127.

An opening 205 exposing the anode wiring 22 is arranged in the connection wiring 20, as shown in FIG. 7. A region where the opening 205 is arranged is positioned inside the region where the anode wiring 22 is arranged. That is, an outer edge of the opening 205 is surrounded by an outer edge of the anode wiring 22. In other words, the connection wiring 20 covers the cathode wiring 23 and a gap arranged between the anode wiring 22 and the cathode wiring 23 (a region not overlapping the anode wiring 22 and the cathode wiring 23 in FIG. 6), and further overlaps the outer edge of the anode wiring 22, in a plan view.

The pattern of the anode wiring 22 and the cathode wiring 23 shown in FIG. 6 and the pattern of the connection wiring 20 shown in FIG. 7 can suppress members in the layers below these patterns from being irradiated with the laser light. That is, among the laser light irradiated on the entire surface, the laser light irradiated on the portion other than the terminal electrode 203 and the connecting electrode 103 is shielded by any one of the anode wiring 22, the cathode wiring 23, and the connection wiring 20. Since the structures of the anode wiring 22, the cathode wiring 23, and the connection wiring 20 are “Al/Ti”, the laser light is reflected by the aluminum on the outermost surface. Therefore, it is possible to suppress an adverse effect on the transistor element or capacity element due to heat generated by the laser irradiation.

### Second Embodiment

### [Cross Sectional Structure of Pixel]

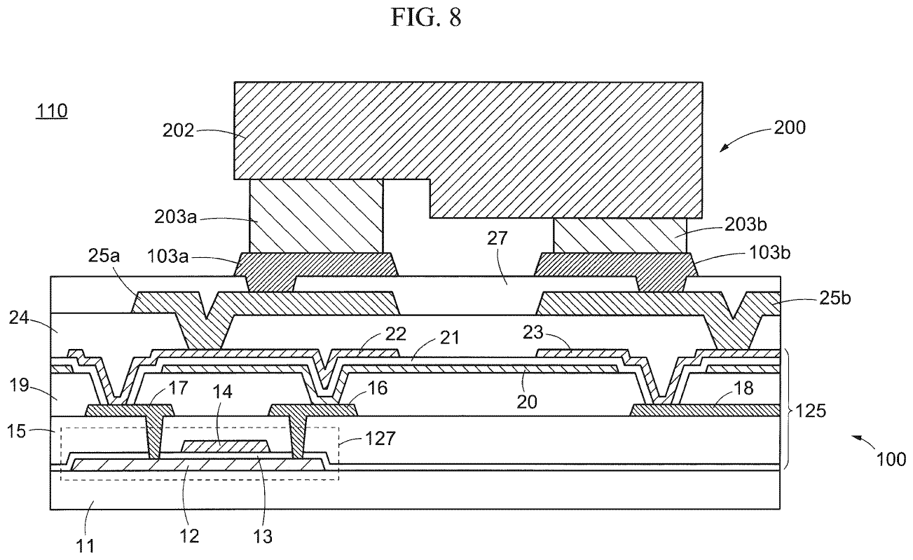

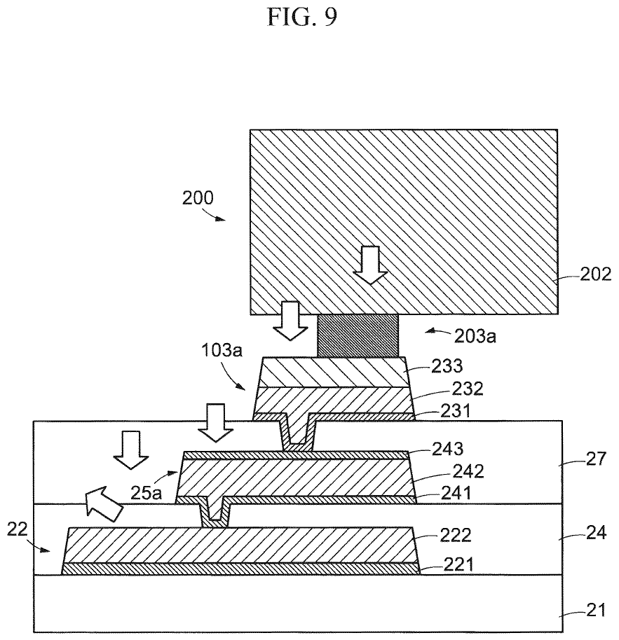

A configuration of the display device 10 according to an embodiment of the present invention will be described with reference to FIG. 8 to FIG. 9. Although the display device according to the second embodiment is similar to the display device according to the first embodiment, it is different from the display device according to the first embodiment in that a conductive layer 25 is arranged between the anode wiring 22 and the connecting electrode 103 and between the cathode wiring 23 and the connecting electrode 103. In the following description, descriptions of portions common to those of the first embodiment will be omitted, and differences from those of the first embodiment will be mainly described.

FIG. 8 is a cross-sectional view showing a configuration of a pixel of a display device according to an embodiment of the present invention. A conductive layer 25a is arranged between the anode wiring 22 and the connecting electrode 103a. Similarly, a conductive layer 25b is arranged between the cathode wiring 23 and the connecting electrode 103b. The conductive layer 25a is connected to the anode wiring 22 via the opening arranged in the insulating layer 24. The conductive layer 25b is connected to the cathode wiring 23 via the opening. An insulating layer 27 is arranged above the conductive layers 25a and 25b. The connecting electrodes 103a and 103b are arranged above the insulating layer 27. The connecting electrode 103a is connected to the conductive layer 25a via an opening arranged in the insulating layer 27. The connecting electrode 103b is connected to the conductive layer 25b via the opening. Part of the conductive layers 25a and 25b is exposed from the connecting electrodes 103a and 103b. In other words, part of the conductive layers 25a and 25b does not overlap the connecting electrodes 103a and 103b in a plan view.

FIG. 9 is a partially enlarged view of FIG. 8. FIG. 9 is an enlarged view of the structure of the anode wiring 22, the conductive layer 25a, the connecting electrode 103a, and the terminal electrode 203a of FIG. 8. The conductive layer 25a includes a first conductive layer 241, a second conductive layer 242, and a third conductive layer 243, as shown in FIG. 9. The first conductive layer 241 is connected to the second conductive layer 222 of the anode wiring 22 via the opening arranged in the insulating layer 24. Part of the third conductive layer 243 is exposed by an opening arranged in the insulating layer 27 and is in contact with the first conductive layer 231 of the connecting electrode 103a. The second conductive layer 242 is arranged between the first conductive layer 241 and the third conductive layer 243.

The third conductive layer 243 is formed of a third material. The third conductive layer 243 is a layer that includes a top surface of the conductive layer 25a. The absorption rate of the third material with respect to infrared radiation is larger than the absorption rate of the second material (the third conductive layer 233) with respect to infrared radiation. Since the infrared absorption rate of the first material (the second conductive layer 222) is smaller than the absorption rate of the second material with respect to infrared radiation as described above, the absorption rate of the third material with respect to infrared radiation is the largest among the first to third materials.

A material having higher heat resistance than the second conductive layer 242, higher adhesion to the lower layer (the insulating layer 24), lower contact resistance with the second conductive layer 222 arranged below the insulating layer 24, and lower contact resistance with the second conductive layer 242 is used as the first conductive layer 241. For example, tantalum, tungsten, molybdenum, or titanium may be used as the first conductive layer 241. A material having a lower resistance than the first conductive layer 241 is used as the second conductive layer 242. For example, aluminum is used as the second conductive layer 242. A material satisfying the above-described characteristics is used as the third conductive layer 243. For example, titanium is used as the third conductive layer 243. The absorption rate of the tin used as the third conductive layer 233 of the connecting electrode 103a with respect to infrared radiation is about 40%, whereas the absorption rate of the titanium used as the third conductive layer 243 with respect to infrared radiation is about 55%.

When laser light is irradiated from above the LED element 200 with the terminal electrode 203a arranged above the connecting electrode 103a as shown in FIG. 9, the laser light is absorbed by the tin arranged as the third conductive layer 233 of the connecting electrode 103a and the titanium arranged as the third conductive layer 243 of the conductive layer 25a. Since the absorption rate of titanium with respect to infrared radiation is larger than tin, the amount of heat generated per unit area is larger in the conductive layer 25a than in the connecting electrode 103a. The conductive layer 25a becomes hotter than the connecting electrode 103a due to laser irradiation, or the heat generated by the connecting electrode 103a is suppressed from diffusing into the conductive layer 25a due to an increase in the temperature of the conductive layer 25a. Therefore, the connecting electrode 103a and the terminal electrode 203a can be efficiently heated, so that the connecting electrode 103a and the terminal electrode 203a can be firmly bonded to each other.

Although a configuration in which the conductive layer 25a is a stacked structure is exemplified in the present embodiment, the configuration is not limited to this configuration. The conductive layer 25a may be a single layer. In this case, if the conductive layer 25a is thin, the heat capacity is small, and the conductive layer 25a may be excessively heated due to heat generated by laser irradiation, and the conductive layer 25a may be destroyed. Therefore, in the case where the conductive layer 25a is a single layer, the thickness needs to be sufficiently large to increase the heat capacity. For example, in the case where the conductive layer 25a is a single layer, the thickness may be 1000 nm or more.

Each of the embodiments (including modifications) described above as an embodiment of the present invention can be appropriately combined and implemented as long as no contradiction is caused. The addition, deletion, or design change of components, or the addition, deletion, or condition change of process as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A display device comprising:
a wiring electrically connected to a transistor of a pixel circuit, a layer including a top surface of the wiring being formed of a first material;
a connecting electrode electrically connected to the wiring, a layer including a top surface of the connecting electrode being formed of a second material; and
an LED element mounted on the connecting electrode,
wherein an absorption rate of the first material with respect to infrared radiation is smaller than an absorption rate of the second material with respect to infrared radiation.

2. The display device according to claim 1, further comprising
an insulating layer covering the top surface of the wiring and arranged with an opening reached to the wiring,
wherein
the connecting electrode is electrically connected to the wiring via the opening, and
an absorption rate of the insulating layer with respect to infrared radiation is smaller than an absorption rate of an oxide of the first material with respect to infrared radiation.

3. The display device according to claim 2, wherein
the first material is aluminum, and
the insulating layer includes a silicon oxide layer or a silicon nitride layer.

4. The display device according to claim 1, wherein
the first material is aluminum, and
a thickness of a layer including a top surface of the wiring is 1 μm or more.

5. The display device according to claim 1, further comprising
a conductive layer arranged below the connecting electrode, a layer including a top surface of the conductive layer being formed of a third material,
wherein
part of the conductive layer does not overlap the connecting electrode in a top view, and
an absorption rate of the third material with respect to infrared radiation is larger than an absorption rate of the second material with respect to infrared radiation.

6. The display device according to claim 5, wherein
the connecting electrode includes a first conductive layer, a second conductive layer and a third conductive layer,
the third conductive layer is formed of the first material, and
the second conductive layer has a barrier property preventing diffusion of a material included in the first conductive layer and the first material included in the third conductive layer.

7. The display device according to claim 5, wherein
the third material is titanium.

8. A display device comprising:
a wiring electrically connected to a transistor of a pixel circuit, a layer including a top surface of the wiring being formed of an aluminum layer;
an insulating layer having an opening and covering a top surface of the aluminum layer in a region other than a region arranged with the opening;
a connecting electrode
arranged above the insulating layer,
including a first conductive layer, a second conductive layer and a third conductive layer, and
electrically connected to the wiring via the opening; and
an LED element mounted on the connecting electrode,
wherein the second conductive layer has a barrier property preventing diffusion of a material included in the first conductive layer and a material included in the third conductive layer.

9. The display device according to claim 8, wherein
the insulating layer includes a silicon oxide layer or a silicon nitride layer.

10. The display device according to claim 8, wherein
a thickness of the aluminum layer is 1 μm or more.

11. The display device according to claim 8, further comprising
a conductive layer arranged below the connecting electrode, a layer including a top surface of the conductive layer being a titanium layer,
wherein part of the titanium layer is exposed from the connecting electrode in a top view.
